(19) United States
(12) Patent Application Publication
(10) Pub. No.: US 2023/0221349 A1
(43) Pub. Date: Jul. 13, 2023

(54) PLUNGER AND METHOD OF MANUFACTURING PLUNGER

(71) Applicant: YOKOWO CO., LTD., Kita-ku, Tokyo (JP)

(72) Inventor: Tomohisa HOSHINO, Tomioka-Shi, Gunma (JP)

(73) Assignee: YOKOWO CO., LTD., Kita-ku, Tokyo (JP)

(21) Appl. No.: 18/009,994

(22) PCT Filed: Jun. 11, 2021
(86) PCT No.: PCT/JP2021/022246

§ 371 Date: Dec. 13, 2022

(30) Foreign Application Priority Data
Jun. 22, 2020 (JP) 2020-106766

(51) Int. Cl. G01R 1/067; G01R 1/073; G01R 3/00

(52) U.S. Cl. CPC G01R 1/06716; G01R 1/073; G01R 3/00

(57) ABSTRACT

A plunger comprising: a tip contactor formed by embedding a first conductive material in a recess part provided in a base; a columnar part formed by embedding a second conductive material in a first opening provided in a first resist film formed over the base, the first opening being located above the recess part; and a receiving part formed by embedding a third conductive material in a second opening provided in a second resist film formed over the first resist film, the second opening being located above the first opening.

### TECHNICAL FIELD

The present invention relates to a plunger and a method of manufacturing a plunger.

### BACKGROUND ART

Various inspection devices have been developed for inspecting characteristics of electronic devices such as integrated circuits (ICs). As disclosed in Patent Document 1, the inspection device includes a plunger. In Patent Document 1, the plunger includes a tip contactor and a columnar part connected to the tip contactor. The tip contactor is formed by polishing.

### RELATED DOCUMENT

### Patent Document

Patent Document 1: Japanese Unexamined Patent Publication No. 2014-25737

### SUMMARY OF THE INVENTION

### Technical Problem

With the miniaturization of the electronic device, arrangement of minute plungers at high density is required for the inspection device in some case. For example, when the tip contactor is formed by polishing as disclosed in Patent Document 1, it may be difficult to miniaturize the plunger.

An example of an object of the present invention is to miniaturize the plunger. Other object of the present invention will be apparent from the description of the present specification.

### Solution to Problem

One aspect of the present invention is a plunger including a tip contactor formed by embedding a first conductive material in a recess part provided in a base, a columnar part formed by embedding a second conductive material in a first opening provided in a first resist film formed over the base, the first opening being located above the recess part, and a receiving part formed by embedding a third conductive material in a second opening provided in a second resist film formed over the first resist film, the second opening being located above the first opening.

Another aspect of the present invention is a method of manufacturing a plunger, the method including embedding a first conductive material in a recess part provided in a base, embedding a second conductive material in a first opening provided in a first resist film formed over the base, the first opening being located above the recess part, and embedding a third conductive material in a second opening provided in a second resist film formed over the first resist film, the second opening being located above the first opening.

### Advantageous Effects of Invention

According to the above aspects of the present invention, the plunger can be miniaturized.

### BRIEF DESCRIPTION OF THE DRAWINGS

FIG. 1 is a perspective cross-sectional view showing the details of an inspection device according to Embodiment 1.

FIG. 2 is a cross-sectional view for describing a method of manufacturing a first plunger according to Embodiment 1.

FIG. 3 is a cross-sectional view for describing the method of manufacturing the first plunger according to Embodiment 1.

FIG. 4 is a cross-sectional view for describing the method of manufacturing the first plunger according to Embodiment 1.

FIG. 5 is a cross-sectional view for describing the method of manufacturing the first plunger according to Embodiment 1.

FIG. 6 is a cross-sectional view for describing the method of manufacturing the first plunger according to Embodiment 1.

FIG. 7 is a cross-sectional view for describing the method of manufacturing the first plunger according to Embodiment 1.

FIG. 8 is a cross-sectional view for describing a method of manufacturing a first plunger according to Embodiment 2.

FIG. 9 is a cross-sectional view for describing a method of manufacturing a first plunger according to Embodiment 3.

### DESCRIPTION OF EMBODIMENTS

In the following, embodiments of the present invention will be described with reference to the drawings. It should be noted that, in all drawings, similar components are designated by the same reference numerals, and the description thereof will not be repeated.

In the present specification, ordinal numbers, such as “first”, “second”, and “third”, are merely used to distinguish similarly named configurations unless otherwise noted, and do not imply any particular feature of the configuration, such as order or importance.

### Embodiment 1

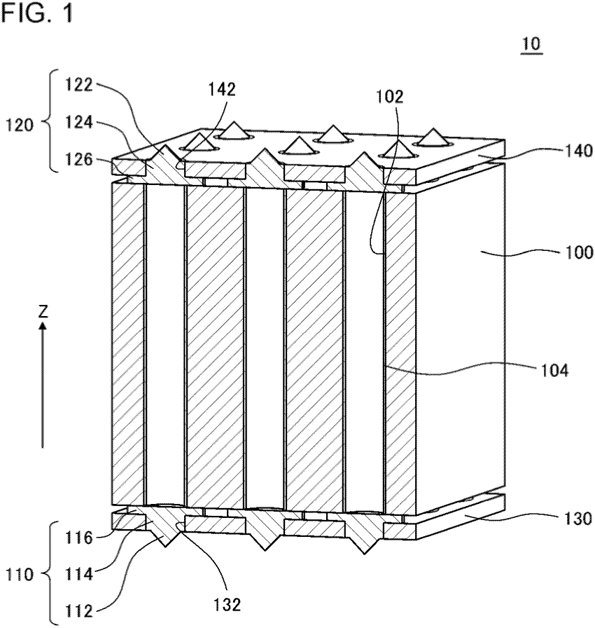

FIG. 1 is a perspective cross-sectional view showing the details of an inspection device 10 according to Embodiment 1.

In FIG. 1, a direction indicated by an arrow indicating the vertical direction Z is the upward direction of the vertical direction Z. A direction opposite to the direction indicated by the arrow indicating the vertical direction Z is the downward direction of the vertical direction Z.

The inspection device 10 includes a first elastomer 100, a plurality of first plungers 110, a plurality of second plungers 120, a first pin plate 130, and a second pin plate 140. Each first plunger 110 includes a first tip contactor 112, a first columnar part 114, and a first receiving part 116. Each second plunger 120 includes a second tip contactor 122, a second columnar part 124, and a second receiving part 126. At least a portion of the first elastomer 100 such as a periphery of a hole 102 described later in the first elastomer 100, a conductive film 104 described later, each first plunger 110, and each second plunger 120 function as a probe. Each first plunger 110 and each second plunger 120 are biased in the vertical direction Z by at least a portion of the first elastomer 100 such as the periphery of the hole 102.

The first elastomer 100 has a sheet shape. In one example, the first elastomer 100 is made of a polymeric material having elasticity, for example a polymeric material such as silicone, polyimide, or styrene-butadiene rubber (SBR).

The first elastomer 100 defines a plurality of holes 102 that penetrate the first elastomer 100 along the vertical direction Z.

The conductive film 104 is formed on an inner wall of each hole 102. In one example, the conductive film 104 includes metal such as at least one selected from the group consisting of nickel, copper, and gold. The conductive film 104 is, for example, a multilayer film of these metals.

Each hole 102 is hollow. In this case, as compared with a case in which the conductive film 104 is formed on the inner wall of the hole 102 and the hole 102 is solid (the hole 102 is filled), a material and a process for making the hole 102 solid are unnecessary, and a manufacturing cost of the inspection device 10 can be reduced.

The first plunger 110 is located below the first elastomer 100. The first plunger 110 overlaps with the first elastomer 100 in the vertical direction Z. Specifically, the first plunger 110 overlaps with the hole 102 in the vertical direction Z. Accordingly, the first plunger 110 can be biased in a direction away from the second plunger 120, that is, downward by the first elastomer 100. The first plunger 110 is electrically connected to the conductive film 104. Accordingly, the first plunger 110 can be electrically connected to the second plunger 120 through the conductive film 104. If the first plunger 110 does not overlap with the hole 102 in the vertical direction Z, an electrical path such as a conductive material embedded in the first elastomer 100 needs to be provided separately from the conductive film 104 in order to electrically connect the first plunger 110 to the conductive film 104. When the first plunger 110 overlaps with the hole 102 in the vertical direction Z, however, the first plunger 110 can be directly connected to the conductive film 104 without through the electrical path such as the conductive material embedded in the first elastomer 100. Accordingly, as compared with a case in which the electrical path is provided, a material and a process for manufacturing the electrical path itself are unnecessary, and the manufacturing cost of the inspection device 10 can be reduced. It should be noted that the first plunger 110 may be offset from the hole 102 in a direction orthogonal to the vertical direction Z. Even in this case, the first plunger 110 can be connected to the conductive film 104 through the electrical path such as the conductive material embedded in the first elastomer 100.

The first tip contactor 112 includes metal such as at least one selected from the group consisting of rhodium, ruthenium, iridium, tungsten, and tantalum.

A width of the first tip contactor 112 is narrowed from a base end to a tip of the first tip contactor 112. The first tip contactor 112 is a conic solid such as a cone or a pyramid, and has a tapered shape from the base end to the tip of the first tip contactor 112. A tip of the first tip contactor 112 has a flat surface of, for example, equal to or more than 1 µm and equal to or less than 20 µm. However, the shape of the tip of the first tip contactor 112 is not limited to this example.

The first columnar part 114 includes metal such as at least one selected from the group consisting of copper and nickel.

The first columnar part 114 is connected to the base end of the first tip contactor 112. The first tip contactor 112 and the first columnar part 114 may be integrated or separate. A height of the first columnar part 114 is, for example, equal to or more than 5 µm and equal to or less than 300 µm. The first columnar part 114 is a column such as a cylinder or a prism. When the first columnar part 114 is a cylinder, a diameter of the first columnar part 114 is, for example, equal to or more than 20 µm and equal to or less than 500 µm. However, the shape of the first columnar part 114 is not limited to this example.

The first receiving part 116 includes metal such as at least one selected from the group consisting of copper and nickel.

The first receiving part 116 is connected to an end portion of the first columnar part 114 opposite to the first tip contactor 112. The first columnar part 114 and the first receiving part 116 may be integrated or separated. The first receiving part 116 has a width wider than a width of the first columnar part 114. A thickness of the first receiving part 116 is, for example, equal to or more than 5 µm and equal to or less than 200 µm. An upper surface of the first receiving part 116 is flat. However, at least one convex part may be formed on the upper surface of the first receiving part 116.

The first pin plate 130 is made of, for example, polyimide, liquid crystal polymer, or glass substrate.

The first pin plate 130 defines a plurality of first through-holes 132. Each of the plurality of first plungers 110 is inserted into each of the plurality of first through-holes 132. The plurality of first plungers 110 can be arranged at a minute pitch (narrow pitch) of, for example, equal to or more than 10 µm and equal to or less than 500 µm.

At least a portion of the first tip contactor 112 is exposed from a lower end of the first through-hole 132 of the first pin plate 130. At least a portion of the first columnar part 114 penetrates the first through-hole 132. The first receiving part 116 is located between an upper surface of the first pin plate 130 and a lower surface of the first elastomer 100. The width of the first receiving part 116 in the left-right direction in the drawing is wider than a width of the first through-hole 132 in the left-right direction in the drawing. Accordingly, the first receiving part 116 is caught by a peripheral portion of an opening end of the first through-hole 132 on the upper surface of the first pin plate 130. In this case, even if the first plunger 110 is biased downward by the first elastomer 100, the first receiving part 116 can be suppressed from exiting downward the first pin plate 130 through the first through-hole 132. Thus, as compared with a case in which the first receiving part 116 is not provided, even if a length of the first plunger 110 (a length of the first columnar part 114) is shortened, the first plunger 110 is unlikely to exit below the first pin plate 130. The length of the first plunger 110 can be shortened, and the first plunger 110 can be applied to an inspection in a high frequency band of equal to or more than 1 GHz and equal to or less than 100 GHz.

The second plunger 120 is located above the first elastomer 100. The second plunger 120 overlaps with the first elastomer 100 in the vertical direction Z. Specifically, the second plunger 120 overlaps with the hole 102 in the vertical direction Z. Accordingly, the second plunger 120 can be biased in a direction away from the first plunger 110, that is, upward by the first elastomer 100. The second plunger 120 is electrically connected to the conductive film 104. Accordingly, the second plunger 120 can be electrically connected to the first plunger 110 through the conductive film 104. If the second plunger 120 does not overlap with the hole 102 in the vertical direction Z, an electrical path such as a conductive material embedded in the first elastomer 100 needs to be provided separately from the conductive film 104 in order to electrically connect the second plunger 120 to the conductive film 104. When the second plunger 120 overlaps with the hole 102 in the vertical direction Z, however, the second plunger 120 can be directly connected to the conductive film 104 without through the electrical path such as the conductive material embedded in the first elastomer 100. Accordingly, as compared with a case in which the electrical path is provided, the material and the process for manufacturing the electrical path itself are unnecessary, and the manufacturing cost of the inspection device 10 can be reduced. It should be noted that the second plunger 120 may be offset from the hole 102 in a direction orthogonal to the vertical direction Z. Even in this case, the second plunger 120 can be connected to the conductive film 104 through the electrical path such as the conductive material embedded in the first elastomer 100.

The second pin plate 140 defines a plurality of second through-holes 142. Each of the plurality of second plungers 120 is inserted into each of the plurality of second through-holes 142 in the same manner as the plurality of first plungers 110 and the first pin plate 130.

According to the present embodiment, as compared with a case in which the plunger is biased by a spring, the first elastomer 100 plays a role of compression and extension of the spring, and the conductive film 104 plays a role of conduction of the spring. If the plunger is biased by the spring, a free length of the spring needs to be short to compare the free lengths of the probe. In this case, however, it is difficult to achieve a sufficient stroke. On the other hand, in the present embodiment, there is no need to use the spring. Accordingly, as compared with a case in which the plunger is biased by the spring, a natural length of the probe can be shortened while achieving the stroke having a sufficient length.

It should be noted that, in the present embodiment, the case has been described in which the first plunger 110 and the second plunger 120 overlap with the first elastomer 100 in the vertical direction Z. However, the first elastomer 100 and the second plunger 120 may overlap with the first elastomer 100 in a direction different from the vertical direction Z.

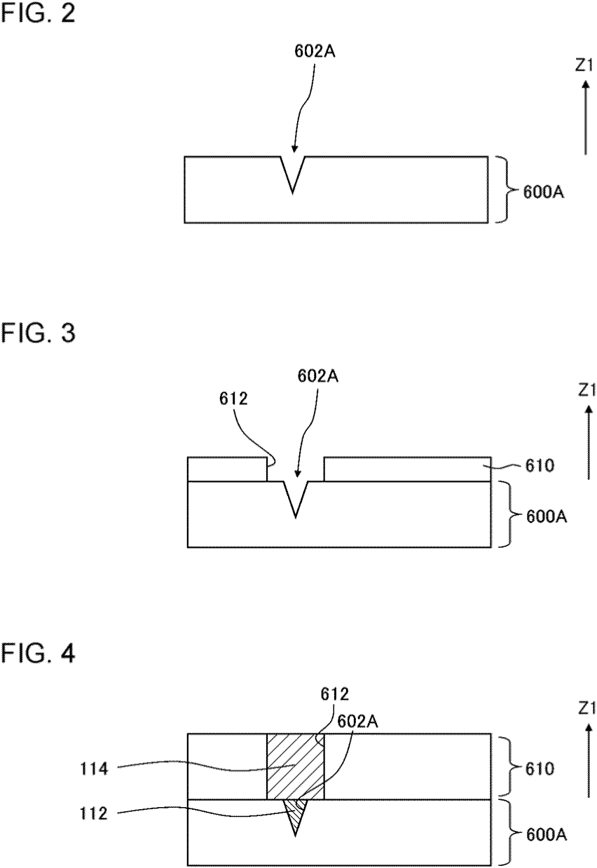

FIGS. 2 to 7 are cross-sectional views for describing a method of manufacturing the first plunger 110 according to Embodiment 1. FIGS. 2 to 7 show a normal direction Z1 of a surface of a metal base 600A on which a recess part 602A is formed.

The method of manufacturing the first plunger 110 will be described with reference to FIGS. 2 to 7. It should be noted that the second plunger 120 can also be manufactured in the same manner as described below.

First, as shown in FIG. 2, the recess part 602A is formed in the metal base 600A. A width of the recess part 602A is narrowed from an opening end toward a bottom end of the recess part 602A. The recess part 602A has a tapered shape. The metal base 600A is, for example, a copper plate. The recess part 602A is formed in the metal base 600A by, for example, punching or pressing.

Next, as shown in FIG. 3, a first resist film 610 is formed on the metal base 600A. A first opening 612 is provided in the first resist film 610. The first opening 612 overlaps with the recess part 602A in the normal direction Z1. A width of the first opening 612 is wider than a width of the opening end of the recess part 602A. That is, the width of the first columnar part 114 may be different from a width of the base end of the first tip contactor 112 due to tolerance between the width of the first opening 612 and the width of the opening end of the recess part 602A. However, the width of the first columnar part 114 may be equal to the width of the base end of the first tip contactor 112. That is, the width of the first opening 612 may be equal to the width of the opening end of the recess part 602A.

Next, as shown in FIG. 4, a first conductive material as the first tip contactor 112 is deposited by plating and the first conductive material is embedded in the recess part 602A. As a result, the first tip contactor 112 is formed in the recess part 602A. Accordingly, the first tip contactor 112 has a plating layer. Next, a thickness of the first resist film 610 is further increased. Next, a second conductive material as the first columnar part 114 is deposited by plating and the second conductive material is embedded in the first opening 612. As a result, the first columnar part 114 is formed in the first opening 612. Accordingly, the first columnar part 114 has a plating layer.

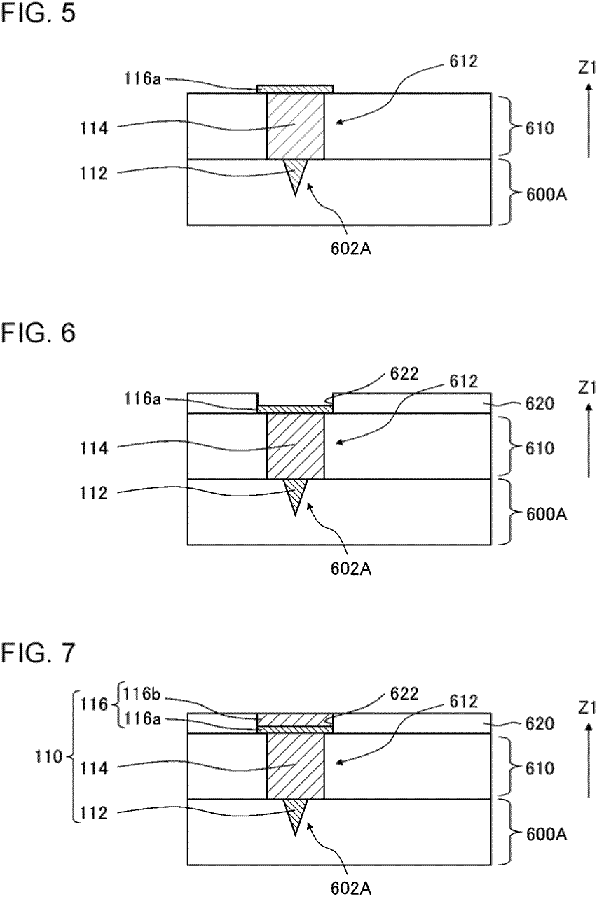

Next, as shown in FIG. 5, a first seed layer 116a is formed on the first columnar part 114 and the first resist film 610.

Next, as shown in FIG. 6, a second resist film 620 is formed on the first resist film 610. A second opening 622 is provided in the second resist film 620. The second opening 622 overlaps with the first opening 612 in the normal direction Z1. A width of the second opening 622 is wider (larger) than the width of the first opening 612.

Next, as shown in FIG. 7, a third conductive material as a first plating layer 116b is deposited by plating and the third conductive material is embedded in the second opening 622. As a result, the first receiving part 116 is formed in the second opening 622. In this case, the first receiving part 116 simultaneously forms a plurality of layers including the first seed layer 116a and the first plating layer 116b.

Next, the first resist film 610 and the second resist film 620 are removed by, for example, chemical solution treatment. Next, the first plunger 110 is removed from the metal base 600A. Next, as necessary, the tip of the first tip contactor 112 is treated by, for example, machining to form the flat surface. It should be noted that the flat surface of the tip of the first tip contactor 112 may be formed by adjusting a shape of the bottom end of the recess part 602A of the metal base 600A.

According to the present embodiment, the first tip contactor 112 can be formed by using the recess part 602A of the metal base 600A as a die. The first columnar part 114 can be formed by using the first opening 612 of the first resist film 610 as a die. The first receiving part 116 can be formed by using the second opening 622 of the second resist film 620 as a die. Accordingly, the first plunger 110 can be miniaturized as compared with a case in which the first tip contactor 112 is formed by polishing. According to the present embodiment, the first plunger 110 can be manufactured at a low cost as compared with a case in which the first tip contactor 112 is formed by polishing. Further, according to the present embodiment, a degree of freedom in a structure of the first plunger 110 can be increased as compared with a case in which the first tip contactor 112 is formed by polishing.

### Embodiment 2

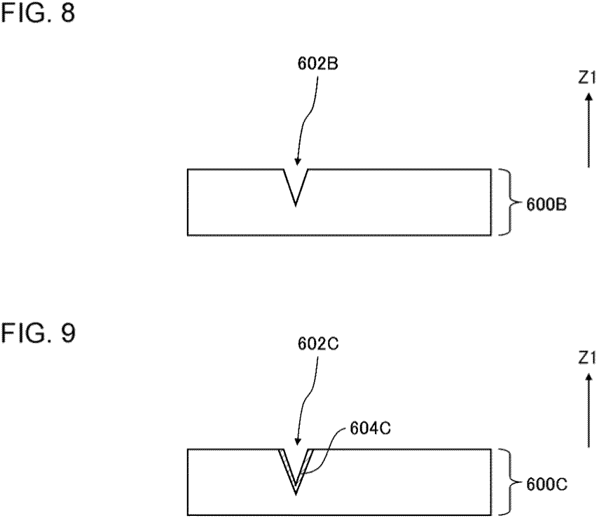

FIG. 8 is a cross-sectional view for describing a method of manufacturing the first plunger 110 according to Embodiment 2. The method according to Embodiment 2 is the same as the method according to Embodiment 1, except for the following points.

In the present embodiment, the first plunger 110 is manufactured as follows.

First, as shown in FIG. 8, a recess part 602B is formed in a semiconductor base 600B. The semiconductor base 600B is, for example, a silicon substrate. The recess part 602B is formed by, for example, anisotropic etching.

The subsequent steps are the same as the steps described with reference to FIGS. 3 to 7 of Embodiment 1.

In general, the flatness of the surface of the semiconductor base 600B according to Embodiment 2 is higher than the flatness of the surface of the metal base 600A according to Embodiment 1. Accordingly, in Embodiment 2, the first tip contactor 112 can be formed by using the recess part 602B provided on the surface having such high flatness as a die. Thus, as compared with Embodiment 1, Embodiment 2 may be suitable for mass production of the first plunger 110.

### Embodiment 3

FIG. 9 is a cross-sectional view for describing a method of manufacturing the first plunger 110 according to Embodiment 3. The method according to Embodiment 3 is the same as the method according to Embodiment 1, except for the following points.

In the present embodiment, the first plunger 110 is manufactured as follows.

First, as shown in FIG. 9, a recess part 602C is formed in a resin base 600C. The resin base 600C is, for example, polyimide or liquid crystal polymer. The recess part 602C is formed by, for example, machining. Next, a seed layer 604C is formed on an inner wall of the recess part 602C. The seed layer 604C is provided for depositing the first conductive material as the first tip contactor 112 by plating.

The subsequent steps are the same as the steps described with reference to FIGS. 3 to 7 of the embodiment.

In general, the resin base 600C according to Embodiment 3 is softer than the metal base 600A according to Embodiment 1. Accordingly, the recess part may be more easily formed in the resin base 600C according to Embodiment 3, than in the metal base 600A according to Embodiment 1.

In the above, the embodiments of the present invention have been described with reference to the drawings, but these are examples of the present invention, and various configurations other than the above can be adopted.

According to the present specification, the following aspects are provided.

### Aspect 1-1

Aspect 1-1 is a plunger including a tip contactor formed by embedding a first conductive material in a recess part provided in a base, a columnar part formed by embedding a second conductive material in a first opening provided in a first resist film formed over the base, the first opening being located above the recess part, and a receiving part formed by embedding a third conductive material in a second opening provided in a second resist film formed over the first resist film, the second opening being located above the first opening.

According to Aspect 1-1, the tip contactor can be formed by using the recess part of the base as a die. The columnar part can be formed by using the first opening of the first resist film as a die. The receiving part can be formed by using the second opening of the second resist film as a die. Accordingly, the plunger can be miniaturized as compared with a case in which the tip contactor is formed by polishing.

### Aspect 1-2

Aspect 1-2 is the plunger according to Aspect 1-1, in which a width of the columnar part is different from a width of a base end of the tip contactor.

According to Aspect 1-2, the width of the columnar part is different from the width of the base end of the tip contactor due to tolerance between the width of the opening end of the recess part of the base for forming the tip contactor and the width of the opening of the resist for forming the columnar part. The width of the columnar part being different from the width of the base end of the tip contactor can prevent the plunger from dropping out from the inspection device.

### Aspect 1-3

Aspect 1-3 is the plunger according to Aspect 1-1 or 1-2, in which the receiving part has a plurality of layers.

According to Aspect 3, the receiving part is formed by forming the plating layer on the seed layer. As a result, the receiving part has the plurality of layers including the seed layer and the plating layer.

### Aspect 2-1

Aspect 2-1 is a method of manufacturing a plunger, the method including embedding a first conductive material in a recess part provided in a base, embedding a second conductive material in a first opening provided in a first resist film formed over the base, the first opening being located above the recess part, and embedding a third conductive material in a second opening provided in a second resist film formed over the first resist film, the second opening being located above the first opening.

According to Aspect 2-1, the tip contactor can be formed of the first conductive material by using the recess part of the base as a die. The columnar part can be formed of the second conductive material by using the first opening of the first resist film as a die. The receiving part can be formed of the third conductive material by using the second opening of the second resist film as a die. Accordingly, the plunger can be miniaturized as compared with a case in which the tip contactor is formed by polishing.

### Aspect 2-2

Aspect 2-2 is the method of manufacturing a plunger according to Aspect 2-1, in which a width of the first opening is different from a width of an opening end of the recess part.

According to Aspect 2-2, the width of the columnar part can be different from the width of the base end of the tip contactor. The width of the columnar part being different from the width of the base end of the tip contactor can prevent the plunger from dropping out from the inspection device.

### Aspect 2-3

Aspect 2-3 is the method of manufacturing a plunger according to Aspect 2-1 or 2-2, in which the third conductive material is formed over a seed layer.

According to Aspect 2-3, the receiving part can be formed by forming the plating layer on the seed layer.

### Aspect 3-1

Aspect 3-1 is a plunger including a tip contactor including a first plating layer of which a width is narrowed from a base end toward a tip, a columnar part including a second plating layer connected to the base end of the tip contactor, and a receiving part connected to an end portion of the columnar part opposite to the tip contactor, the receiving part including a third plating layer having a width wider than a width of the columnar part.

According to Aspect 3-1, the tip contactor can be formed by using the recess part of the base as a die. The columnar part can be formed by using the first opening of the first resist film as a die. The receiving part can be formed by using the second opening of the second resist film as a die. Accordingly, the plunger can be miniaturized as compared with a case in which the tip contactor is formed by polishing.

### Aspect 3-2

Aspect 3-2 is the plunger according to Aspect 3-1, in which a width of the columnar part is different from a width of a base end of the tip contactor.

According to Aspect 3-2, the width of the columnar part is different from the width of the base end of the tip contactor due to tolerance between the width of the opening end of the recess part of the base for forming the tip contactor and the width of the opening of the resist for forming the columnar part. The width of the columnar part being different from the width of the base end of the tip contactor can prevent the plunger from dropping out from the inspection device.

### Aspect 3-3

Aspect 3-3 is the plunger according to Aspect 3-1 or 3-2, in which the receiving part has a plurality of layers.

According to Aspect 3-3, the receiving part is formed by forming the third plating layer on the seed layer. As a result, the receiving part has the plurality of layers including the seed layer and the third plating layer.

This application claims priority based on Japanese Patent Application No. 2020-106766 filed on Jun. 22, 2020, the entire disclosure of which is incorporated herein by reference.

REFERENCE SIGNS LIST

| | |
|---|---|
| 10 | inspection device |
| 100 | first elastomer |
| 102 | hole |
| 104 | conductive film |
| 110 | first plunger |
| 112 | first tip contactor |
| 114 | first columnar part |
| 116 | first receiving part |
| 116 a | first seed layer |
| 116 b | first plating layer |
| 120 | second plunger |
| 122 | second tip contactor |
| 124 | second columnar part |
| 126 | second receiving part |
| 130 | first pin plate |
| 132 | first through-hole |
| 140 | second pin plate |
| 142 | second through-hole |
| 600A | metal base |
| 600B | semiconductor base |
| 600C | resin base |
| 602A | recess part |
| 602B | recess part |
| 602C | recess part |
| 604C | seed layer |
| 610 | first resist film |
| 612 | first opening |
| 620 | second resist film |
| 622 | second opening |
| Z | vertical direction |
| Z1 | normal direction |

1. A plunger comprising:
a tip contactor formed by embedding a first conductive material in a recess part provided in a base;
a columnar part formed by embedding a second conductive material in a first opening provided in a first resist film formed over the base, the first opening being located above the recess part; and
a receiving part formed by embedding a third conductive material in a second opening provided in a second resist film formed over the first resist film, the second opening being located above the first opening.

2. The plunger according to claim 1,
wherein a width of the columnar part is different from a width of a base end of the tip contactor.

3. The plunger according to claim 1,
wherein the receiving part has a plurality of layers.

4. A method of manufacturing a plunger, the method comprising:
embedding a first conductive material in a recess part provided in a base;
embedding a second conductive material in a first opening provided in a first resist film formed over the base, the first opening being located above the recess part; and
embedding a third conductive material in a second opening provided in a second resist film formed over the first resist film, the second opening being located above the first opening.

5. The method of manufacturing a plunger according to claim 4,
wherein a width of the first opening is different from a width of an opening end of the recess part.

6. The method of manufacturing a plunger according to claim 4,
wherein the third conductive material is formed over a seed layer.
